(19) United States
(12) Patent Application Publication
(10) Pub. No.: US 2007/0094554 A1
(43) Pub. Date: Apr. 26, 2007

(54) Chip specific test mode execution on a memory module

(76) Inventors: Martin Versen, Feldkirchen-Westerham (DE); Oliver Kiehl, Charlotte, VT (US)

Correspondence Address: EDELL, SHAPIRO & FINNAN, LLC, 1901 RESEARCH BLVD., SUITE 400, ROCKVILLE, MD, 20850, US

(21) Appl. No.: 11/253,716

(22) Filed: Oct. 20, 2005

(51) Int. Cl. G11C 29/00

(52) U.S. Cl. 714/718

(57) ABSTRACT

A test mode for component-specific testing of a memory module. Data is written to and stored in each memory component of a memory module, which data indicates whether the memory component is to execute a particular test mode. Upon receiving a test mode command supplied in common to all of the memory components on the memory module, each memory component examines the data to determine whether it is to execute a test mode command supplied contemporaneously therewith or subsequently supplied test mode commands.

### BACKGROUND OF THE INVENTION

The present invention is directed to semiconductor memory circuits, and more specifically to a technique for executing a component-specific test mode on select memory components of a memory module.

The functionality of semiconductor memory integrated circuits, such as dynamic random access memory (DRAM) chips, is tested during production with respect to a functional specification of the DRAM chip. The development of DRAMs and test modes for DRAMs greatly depend on the analysis of DRAM failures. DRAMs are often mounted or fitted to a memory module, such as a single in-line memory module (SIMM) or a dual in-line memory module (DIMM) for use in system applications. An example of a SIMM is shown in FIG. 1, where memory module 10 comprises four memory chips 20(1), 20(2), 20(3) and 20(4).

As shown in FIG. 1, all of the address and command lines to the memory module 10 are connected in parallel to all of the memory components on the memory module. Only the data lines (DQs) on the memory module are chip specific. Consequently, when a conventional test mode is executed on a memory module in an application environment, the test mode affects not only the desired chip of the module, but also the other chips connected with it in parallel even though each chip outputs data on its own data lines. Such a configuration may lead to unwanted test failures of different chips on the module, and possibly even system failures.

It would be desirable to provide for chip specific test mode capabilities of a memory module.

### SUMMARY OF THE INVENTION

Briefly, a test mode is provided for component-specific testing of a memory module. Data is written to data lines of each memory component for storage in each memory component. This data indicates whether the memory component is to execute a particular test mode. Upon receiving a test mode command supplied to the memory module, each memory component examines the data to determine whether it is to execute test mode commands. In this way, one or more memory components can be selected to execute a test mode while other memory components stay in a normal mode or otherwise do not execute the test mode.

### BRIEF DESCRIPTION OF THE DRAWINGS

FIG. 1 is a diagram of a prior art memory module.

FIG. 2 is a diagram of a memory module employing the chip-specific test mode according to the invention.

FIG. 3 is a more detailed block diagram of a memory module employing the chip-specific test mode according to the invention.

FIG. 4 is a diagram showing a memory module and test mode adaptor card performing a chip-specific test mode according to the invention.

FIG. 5 is a flow chart showing a process according to one embodiment of the invention.

FIG. 6 is a block diagram showing an embodiment according to the invention.

FIG. 7 is a flow chart of the test mode according to the embodiment on FIG. 6.

### DETAILED DESCRIPTION

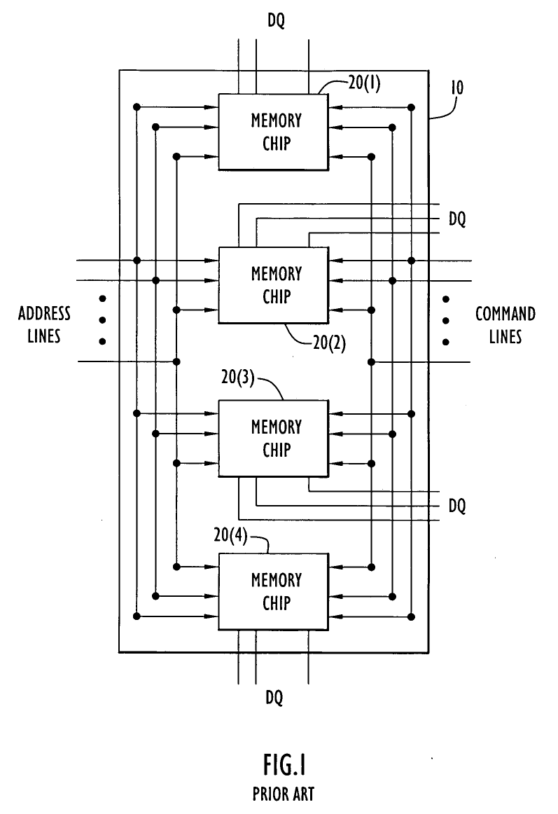

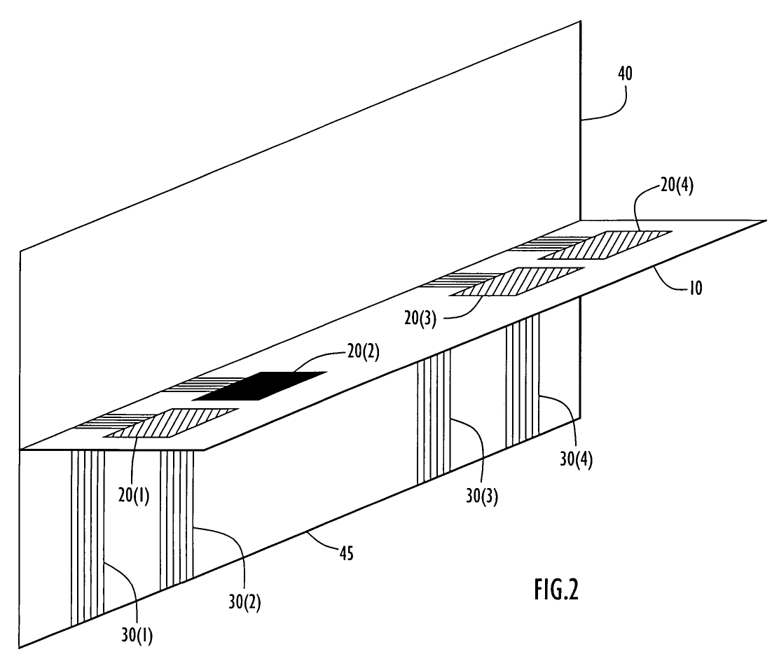

Referring first to FIG. 2, a memory module 10 is shown, such as a single in-line memory module (SIMM). The memory module 10 comprises a plurality of semiconductor memory integrated circuit (IC) chips or components. In this example, there are four memory components 20(l), 20(2), 20(3) and 20(4). There may be more or fewer memory components on the memory module 10 depending on a particular system application. The techniques described herein may also be used on a DIMM. A test mode adapter card 40 has a system connector 45 and supplies test mode commands to the memory module 10 and receives test results therefrom. Lines 30(1), 30(2), 30(3) and 30(4) correspond to the address lines and command lines (connected in parallel to corresponding memory components as shown in FIG. 1) and to the component-specific data lines.

As explained above, all of the address and command lines are connected in parallel to all of the memory components. Test mode commands are supplied to the memory components via the command lines. Thus, the same test mode command is supplied to the memory components in parallel. Only the data lines to/from the memory module 10 are component specific. According to the invention, while a common test mode command is supplied to each of the memory components on the memory module, the (component-specific) data lines for each memory module are used to select whether a memory component will execute the commonly supplied test mode command. More specifically, selectivity information in the form of test mode mask information is supplied to the unique data lines of each memory component for storage in the memory components. Each memory component uses this selectivity information to determine whether to execute a test mode command that may be supplied contemporaneously therewith to the memory module, or supplied subsequently.

For example, one of the memory components, such as component 20(2), is selected to execute a component or chip specific test mode. For this reason, component 20(2) is shaded darker to contrast it from the other memory components 20(1), 20(3) and 20(4) that do not participate in this exemplary test mode and are in normal operation. Said another way, memory components 20(1), 20(3) and 20(4) are masked from the test mode. It should be understood that one or more of the memory components 20(1) to 20(4) may be selected to participate in a test mode.

According to the present invention, since the data lines are memory component specific, they are used to distinguish whether a memory component (chip) is to be part of a test mode or not. For example, a code, called a test mode code word is supplied to the memory module by the test mode adaptor card 40. The CPU in the test mode adaptor card 40 writes the test mode mask code word to a linear CPU address that corresponds to a particular address for each portion of the code word corresponding to the DQs of each memory component. In so doing, the CPU chipset distributes corresponding portions of the code word to an address of each memory component via the DQs for the corresponding memory component. Each portion of the test mode code word signifies how that memory component responds to a particular test mode command, i.e., to execute test mode procedures or not.

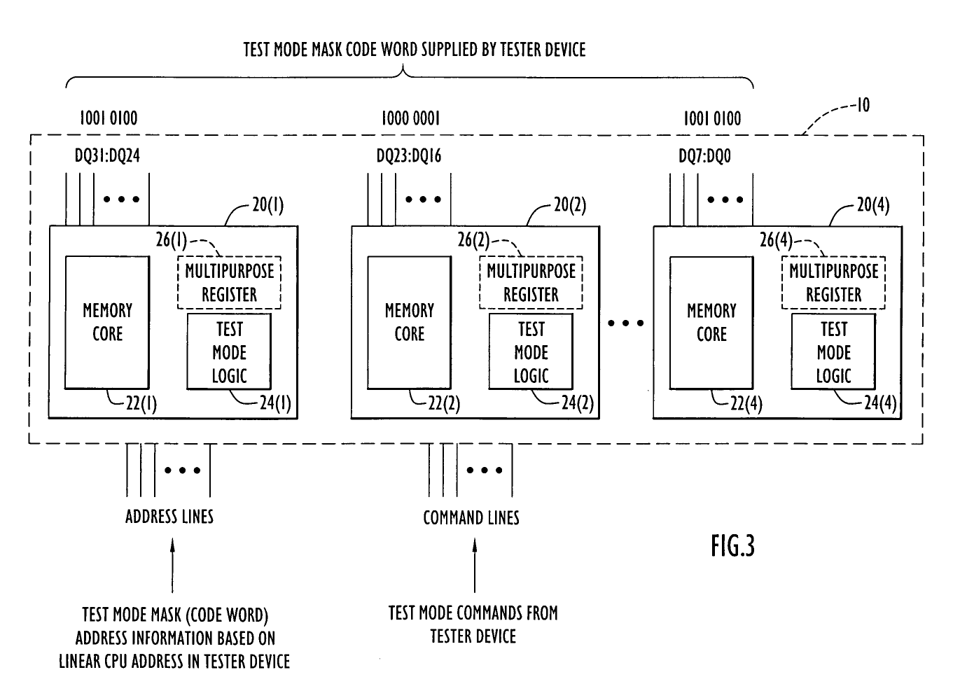

Turning to FIGS. 3-5, in one embodiment of the invention, the storage location in the memory component may be a special designated address in the memory core 22(i) of each memory component 20(i), or a test mode address associated with a certain test mode. In either case, a test mode logic circuit 24(i) examines the content of that memory location, in response to a particular test mode command, to determine whether that memory component 20(i) participates in the test mode.

Using knowledge of the address split among the components 20(1) to 20(4), a certain linear CPU address is edited and used to store a test mode code word in the memory components. Alternatively, the storage location may be at least one designated register in the test mode logic circuit of each memory component. The CPU chipset (not shown) translates the linear CPU address into an (x,y) memory address. Corresponding portions of the test mode code word are consequently written into the memory array location with the corresponding (x,y) coordinates in each memory component. A data word (e.g., 32 bits) of a linear CPU address represents the data of a given memory address for 2, 4 or 8 memory components, depending on the component organization on the memory module. In a “×8” data word organization, this means that each of four memory components is accessed to write one 32-bit data word.

For example, if the test mode code word is “94-81-94-94” (hexadecimal), the “94” would be in three component addresses, while the “81” is in the remaining component address, i.e., the component that is to execute the test mode. During writing of the “94-81-94-94” data word into one (x,y) address, each of four physical components (in a “×8” data word organization) is accessed. The first, third and fourth components get the hexadecimal data word “94” or “1001 0100” in binary representation for the component data lines DQ7 . . . DQ0 as shown in Table 1 below and in FIG. 3.

TABLE 1

| | DQ7:DQ0 for Component | | | |
|---|---|---|---|---|
| | Component | Component | Component | Component |
| | 20(1) | 20(2) | 20(3) | 20(4) |
| DQs for a | DQ31:DQ24 | DQ23:DQ16 | DQ15:DQ8 | DQ7:DQ0 |
| Data Word | | | | |
| Hexadecimal | 94 | 81 | 94 | 94 |
| Binary | 1001 0100 | 1000 0001 | 1001 0100 | 1001 0100 |

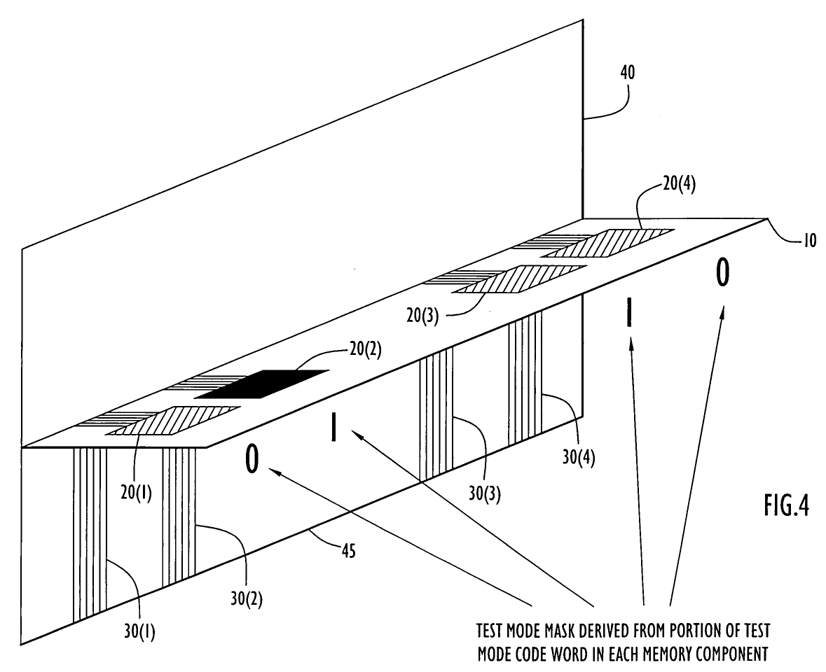

In this example, data at the (x,y) address for components 1, 3 and 4 are identical, but for component 2 it is different. The test mode execution would result in a test mode exit of the three masked components, 20(1), 20(3) and 20(4) in FIG. 1, while component 20(2) would execute the test mode. That is, test mode logic circuits 24(1), 24(3) and 24(4) would interpret the bit pattern “1001 0100” to exit the test mode or stay in a normal operation mode (e.g., a test mode mask bit of “0” as shown in FIG. 4), while test mode logic circuit 24(2) would interpret the bit pattern “1001 0001” to execute all subsequently issued test mode commands and test mode procedures (e.g., a test mode mask bit of “1” as shown in FIG. 4).

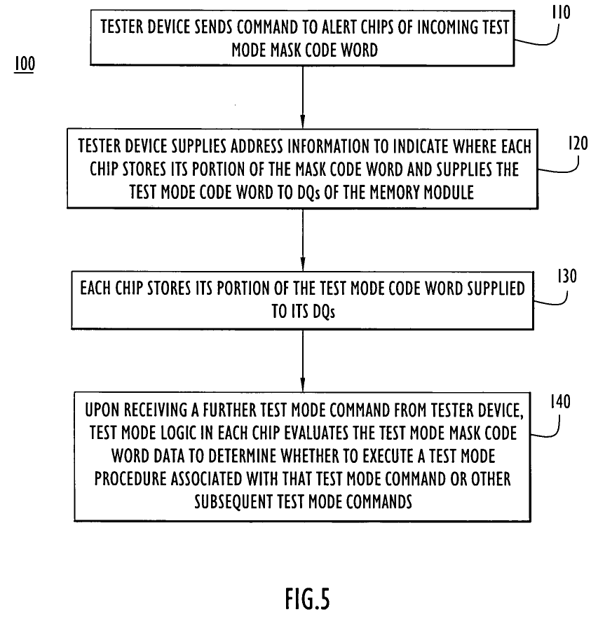

FIG. 5 depicts an exemplary sequence 100 of events that may be performed according to the embodiment shown in FIGS. 3 and 4. In step 110, the tester device (i.e., test mode adaptor card 40 shown in FIG. 1) sends a test mode command to the memory module at the command lines to alert each of the chips of an incoming test mode mask code word. In step 120, the tester device supplies the address information to the address lines of the memory module to indicate where each chip stores its portion of the test mode mask code word, and also supplies the test mode mask code word to the DQs of the memory module. In step 130, each chip stores its portion of the test mode mask code word supplied to its DQs at the address based on the address information supplied in step 120. In step 140, upon receiving a further (particular) test mode command from the tester device, the test mode logic in each chip evaluates the test mode mask code word data to determine whether to execute test mode procedures associated with that test mode command or certain subsequently supplied test mode commands.

There are many variations to the sequence 100 shown in FIG. 5. For example, the test mode mask code word writing and evaluating process may be part of a single test mode command, where the address and test mode mask code word are supplied to the address lines and DQs, respectively, of the memory module contemporaneously with a test mode command to alert the chips of the test mode mask writing process. The test mode logic may be programmed to respond to a particular test mode command so as to control each chip to read the address and data supplied to the DQ and interpret that data as a test mode mask with respect to subsequently supplied test mode commands. Further still, it is envisioned that each memory component may store multiple test mode mask code word data, each stored at a different address in each chip. Each test mode mask code word data is evaluated in response to receiving a corresponding test mode command. In this way, a sequence of test procedures may be separately and selectively invoked on the memory chips, based on the content of the test mode mask code word data for a plurality of test mode masks. Examples of test mode procedures that may be selectively executed on a memory chip are internal voltage trimmings and internal timing modifications.

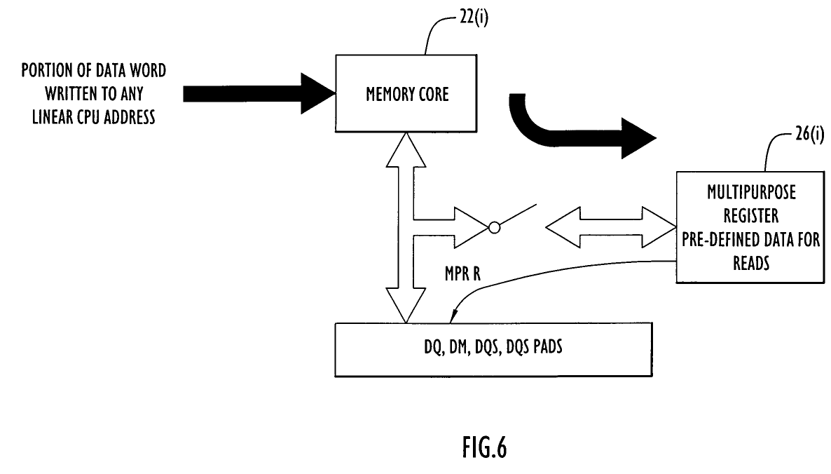

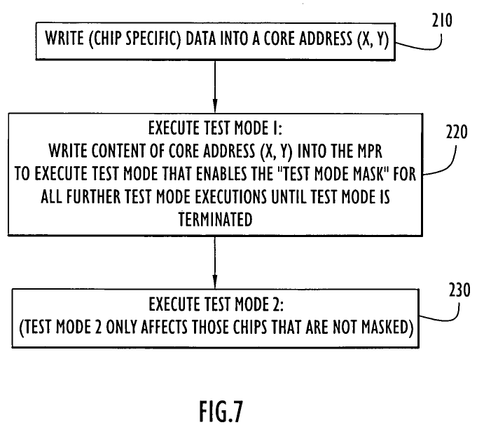

Referring still to FIG. 3 together with FIGS. 6 and 7, another embodiment for configuring the memory module 10 for a chip specific test mode will be described using a multipurpose register (MPR) 26(i) in each memory component 20(i). The MPR is a pre-defined register for read operations. Specifically, the Double Data Rate 3 (DDR3) standard defines the MPR for read operations only, not for write operations. According to this embodiment, test mode execution is masked with the MPR content, and the test mode code word portion is written from an address in the memory core 22(i) to the MPR 26(i) in each memory component 20(i).

In accordance with this embodiment, the first step of the test mode process involves, in step 210, writing chip specific data to a memory core address (x,y) in the same manner as described above in connection with FIGS. 3-5. Next, in step 220, a first test mode is executed, e.g., Test Mode 1, for example, whereby in response to a first test mode command, each memory component 20(i) writes the content at its core address (x,y) to its corresponding MPR 26(i). This sets up the “Test Mode Mask” for all further test mode executions until the test mode procedure is terminated. Also, in step 220, the test mode logic circuit 24(i) in each memory component 20(i) examines the content of the MPR 26(i) to determine whether to execute subsequent test mode commands or to enter (or stay in) a test mode exit (or normal operation mode). Next, in step 230, a second test mode, e.g., Test Mode 2, is executed, whereby in response to a second test mode command, one or several test mode procedures are executed only those memory components on the memory module that are not masked, e.g., memory component 20(2) in this example.

The advantage of using the MPR in a memory chip is that the MPR is already a designed element in the DDR3 standard, and it can be reused for the purposes described herein. Therefore, memory devices that are designed to comply with the DDR3 standard can employ these techniques without providing any additional silicon area.

The system and methods described herein may be embodied in other specific forms without departing from the spirit or essential characteristics thereof. The foregoing embodiments are therefore to be considered in all respects illustrative and not meant to be limiting.

What is claimed is:

1. A test mode method for a memory module that comprises a plurality of memory components, comprising selectively executing a test mode on one of the plurality of memory components.

2. The method of claim 1, and further comprising writing data to an address of each of the plurality of memory components, wherein the data indicates whether the memory component is to execute the test mode; and in each memory component, evaluating the contents of the address to determine whether the memory component is selected to execute the test mode.

3. The method of claim 2, wherein writing comprises writing first data to the memory component that is selected to execute the test mode and writing second data to the memory components that are not selected to execute the test mode.

4. The method of claim 2, wherein in response to a command supplied to the memory module, further comprising in each memory component, writing the data that has been stored as the address to a multipurpose register; and in each memory component, evaluating the contents of the multipurpose register to determine whether the memory component is selected to execute the test mode.

5. A memory module, comprising a plurality of memory components, each of the memory components storing data that, in response to a command, is evaluated in order to determine whether to execute a test mode.

6. The memory module of claim 5, wherein a first bit pattern stored at an address of select one or more of the plurality of memory components that is to execute the test mode and a second bit pattern is stored at the address of the remaining memory components that are to not execute the test mode.

7. The memory module of claim 6, wherein each memory component comprises a multipurpose register and a test mode logic circuit, and wherein in response to a command supplied to the memory module, each of the memory components writes its corresponding stored bit pattern to its multipurpose register, and wherein the test mode logic circuit in each memory component examines the contents of the multipurpose register to determine whether to execute the test mode.

8. The memory module of claim 6, wherein each memory component comprises a test mode logic circuit that examines the data to determine whether to execute the test mode.

9. The memory module of claim 8, wherein the test mode logic comprises a register that stores the data supplied to each memory component from corresponding data lines for each memory component.

10. A method for executing a test mode on select one or more components on a memory module, comprising: reading data stored in each memory component of the memory module, wherein the data indicates whether the corresponding memory component is to execute the test mode; and in each memory component, evaluating the data read from the address to determine whether the memory component executes the test mode in response to test mode command.

11. The method of claim 10, and further comprising writing said data to the data lines of each memory component at an address of each of the plurality of memory components.

12. The method of claim 10, wherein in each memory component, further comprising writing said data stored at the address of each memory component to a multipurpose register; and reading the contents of the multipurpose register of each memory component, wherein evaluating comprises evaluating the contents of the multipurpose register.

13. A method for selectively executing a test mode on one or more of a plurality of memory components of a memory module, comprising: supplying data to data lines of the memory module to store in each memory module data that indicates whether the memory module is to execute a test mode command; supplying a common test mode command to each of the memory components on the memory module; and in each memory component evaluating said data to determine whether to execute a test mode procedure associated with the test mode command.

14. The method of claim 13, wherein supplying comprises writing first data to the memory component that is to execute the test mode procedure and writing second data to the memory components that are not to execute the test mode.

15. A test mode method for a memory component in a memory module that comprises a plurality of memory components, comprising evaluating data stored in said memory component in response to a first test mode command, said data indicating whether the memory component is to execute a test mode procedure associated with said test mode command, and executing the test mode procedure depending on said data.

16. The method of claim 15, wherein evaluating comprises evaluating data stored at a particular memory address designated for said test mode command.

17. The method of claim 15, and further comprising writing said data to an address of the memory component; and reading the contents at said address in response to said first test mode command.

18. The method of claim 15, wherein in response to said first test mode command, in each memory component writing said data stored to a multipurpose register and evaluating the content of the multipurpose register to determine whether the memory component is to execute the test mode procedure; and in response to a second test mode command, executing said test mode procedure.

19. A memory module comprising a plurality of memory components, each memory component comprising storage means for storing data that indicates whether the memory component is to execute a particular test mode command; and means for evaluating the data in response to a test mode command to determine whether the memory component executes the particular test mode command.

20. The memory module of claim 19, wherein the data comprises a first bit pattern stored at an address of said select one or more of the plurality of memory components and the data comprises a second bit pattern stored at the corresponding address of the remaining memory components.
